(19) United States
(12) Patent Application Publication
(10) Pub. No.: US 2020/0273683 A1
(43) Pub. Date: Aug. 27, 2020

(54) PLASMA PROCESSING METHOD AND PLASMA PROCESSING APPARATUS

(71) Applicant: Hitachi High-Technologies Corporation, Minato-ku, Tokyo (JP)

(72) Inventors: Yuta TAKAGI, Tokyo (JP); Kosa HIROTA, Tokyo (JP); Yoshiharu INOUE, Tokyo (JP); Masakazu MIYAJI, Tokyo (JP)

(21) Appl. No.: 16/642,187

(22) PCT Filed: Feb. 27, 2019
(86) PCT No.: PCT/JP2019/007598

§ 371 Date: Feb. 26, 2020

(51) Int. Cl. H01J 37/32

(52) U.S. Cl. CPC H01J 37/32862; H01J 2237/334; H01J 37/32449; H01J 37/32146

(57) ABSTRACT

A plasma processing method includes an etching step of etching a wafer in a chamber, a plasma cleaning step of removing a particle on an inner wall of the chamber by introducing a gas containing a halogen element into the chamber by a plasma processing method for removing remaining halogen or the like in the chamber in a short time and improving throughput, and a remaining halogen removing step of removing the halogen element remaining in the chamber in the plasma cleaning step by alternately repeating an on state and an off state of the plasma containing oxygen in the chamber.

### TECHNICAL FIELD

The present invention relates to a plasma processing method and a plasma processing apparatus.

### BACKGROUND ART

In a manufacturing process of a semiconductor device, it is required to deal with miniaturization and integration of components in a semiconductor device. For example, in an integrated circuit or a nano-electromechanical system, nanoscaling of a structure is further promoted. In general, in the manufacturing process of the semiconductor device, a lithography technique is used to form a fine pattern. In this technique, a pattern of a device structure is applied on a resist layer, and a substrate exposed by the pattern on the resist layer is selectively removed by etching. In a subsequent processing step, an integrated circuit can be formed by depositing other materials in an etched region.

In recent years, with the progress of the miniaturization in semiconductor manufacturing such as the integrated circuit, development of a cleaning technique for stabilizing an atmosphere in a chamber progresses in order to more precisely control an etching reaction in the chamber.

However, if etching is performed immediately after cleaning, there is also a problem that an etching rate becomes unstable due to gas remaining in the chamber. In addition, there is also a problem that a particle existing in the chamber adheres to the substrate by cleaning, and adversely affects wiring formation and the like. Particularly, the particle adhered to the substrate significantly reduces a yield of the semiconductor device.

Causes of the particle include: (a) corrosion of a chamber sidewall, adhesion of byproducts; and (b) formation of compounds formed of a halogen remaining in the chamber. As a measure against the particle caused by (a), a method of stabilizing the atmosphere in the chamber by performing plasma-cleaning using sulfur hexafluoride (SF₆), nitrogen trifluoride (NF₃), and oxygen (O₂) is used. As a measure against the particle and a variation in the etching rate caused by (b), cleaning is performed with oxygen plasma.

PTL 1 discloses a technique of removing fluorine remaining in a chamber after cleaning is performed with nitrogen trifluoride (NF₃). PTL 2 discloses a technique of performing plasma-cleaning inside a chamber by alternately repeating a plasma generation state and a plasma non-generation state.

### CITATION LIST

### Patent Literature

PTL 1: JP-A-2016-225567

PTL 2: JP-A-2010-140944

### SUMMARY OF INVENTION

### Technical Problem

In the technique disclosed in PTL 1, since it takes a long time to completely remove remaining nitrogen or fluorine, the number of products processed per unit time (throughput) is small, and productivity is poor. In addition, the plasma-cleaning disclosed in PTL 2 is not intended to remove remaining nitrogen or remaining halogen in the chamber.

An object of the invention is to provide a plasma processing method and a plasma processing apparatus capable of removing the remaining halogen or the like in the chamber in a short time and improving the throughput of a cleaning process.

### Solution to Problem

In order to solve the problems, a typical plasma processing method of the invention, which is a plasma processing method for plasma processing a sample in a processing chamber, includes: a first step of plasma processing the sample; a second step of performing plasma-cleaning inside the processing chamber using a fluorine-containing gas after the first step; and a third step of performing the plasma-cleaning inside the processing chamber using plasma generated by a pulse-modulated radio frequency power and an oxygen gas after the second step.

### Advantageous Effect

According to the invention, a remaining halogen or the like in the chamber can be removed in a short time, and a throughput of a cleaning process can be improved. Problems, configurations, and effects other than those described above will become apparent from the following description of the embodiment.

### BRIEF DESCRIPTION OF DRAWINGS

FIG. 1 is a cross-sectional view showing an example of a schematic structure of a plasma processing apparatus according to an embodiment of the invention.

FIG. 2 is a flowchart showing an example of a procedure of a plasma processing method using the plasma processing apparatus shown in FIG. 1.

FIG. 3 is a cross-sectional view showing an example of a state in which fluorine remains on a chamber sidewall in the plasma processing apparatus shown in FIG. 1.

FIG. 4 is a graph of the number of particles that may be present near the sidewall and a potential of the chamber sidewall according to an embodiment of the invention.

FIG. 5 is a graph showing an effect of the invention according to the embodiment of the invention.

### DESCRIPTION OF EMBODIMENTS

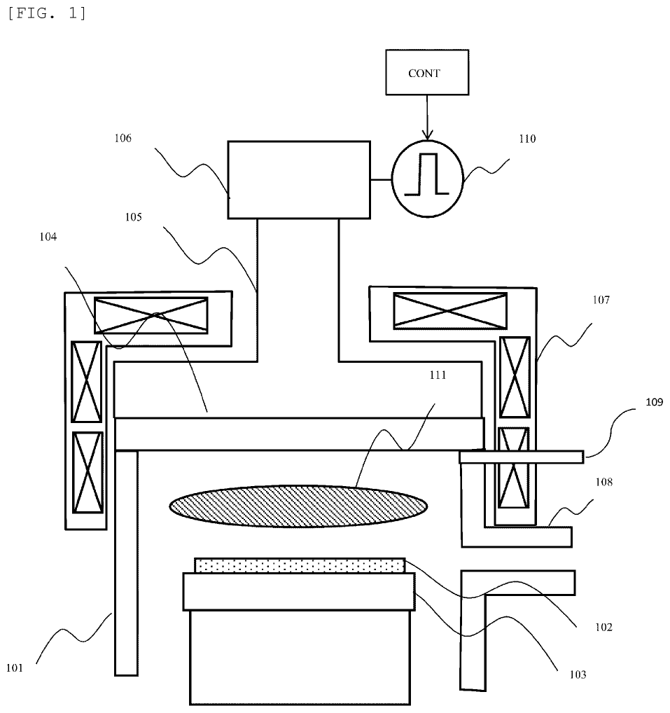

A specific embodiment of a plasma processing method according to the invention will be described below. First, an example of a plasma etching device (plasma processing apparatus) for performing the plasma processing method will be described with reference to drawings. FIG. 1 is a schematic cross-sectional view of an electron cyclotron resonance (hereinafter referred to as ECR) plasma etching device using a microwave and a magnetic field in a plasma generation unit.

The ECR plasma etching device includes a chamber 101 which is a plasma processing chamber and capable of evacuating inside the chamber, a sample stage 103 on which a wafer 102 is placed as a sample, a quartz microwave transmission window 104 provided on an upper surface of the chamber 101, a waveguide 105 provided above the microwave transmission window 104, a magnetron 106 that oscillates a microwave, a first radio frequency power supply 110 that supplies a radio frequency power to the magnetron 106, a solenoid coil 107 provided around the chamber 101, a gas supply pipe 109 that introduces a process gas into the chamber, and a control device CONT that controls the first radio frequency power supply 110. The control device CONT includes a storage unit in which a program for executing a first step, a second step, and a third step, which will be described later, is stored.

The first radio frequency power supply 110 has a function of performing pulse-modulation on the microwave oscillated from the magnetron 106 under control of the control device CONT. Here, an inverse number of a cycle in which oscillations (ON) and interruptions (OFF) of the microwave are repeated is defined as a pulse frequency, and a value obtained by dividing an oscillation time by a pulse cycle is defined as a duty ratio.

Next, an operation of the plasma etching device will be described. After being carried into the chamber 101 through a wafer load port 108, the wafer 102 is electrostatically adsorbed to the sample stage 103 by an electrostatic adsorption power supply (not shown). Next, the process gas is introduced into the chamber 101 from the gas supply pipe 109.

The chamber 101 is evacuated by a vacuum pump (not shown) and adjusted to a predetermined pressure (for example, 0.1 Pa to 50 Pa). Next, by supplying the radio frequency power from the radio frequency power supply 110 to the magnetron 106, a microwave with a frequency of 2.45 GHz is oscillated from the magnetron 106 and is propagated into the chamber 101 via the waveguide 105.

The process gas is excited by an interaction between a magnetic field generated by the solenoid coil 107 and the microwave, and plasma 111 is generated in a space above the wafer 102. On the other hand, a bias is applied to the sample stage 103 by a second radio frequency power supply (not shown), and ions in the plasma 111 are vertically accelerated and incident on the wafer 102.

In addition, the second radio frequency power supply (not shown) can apply a continuous bias power or a time-modulated bias power to the sample stage 103. The wafer 102 is anisotropically etched by actions of radicals and the ions in the plasma 111.

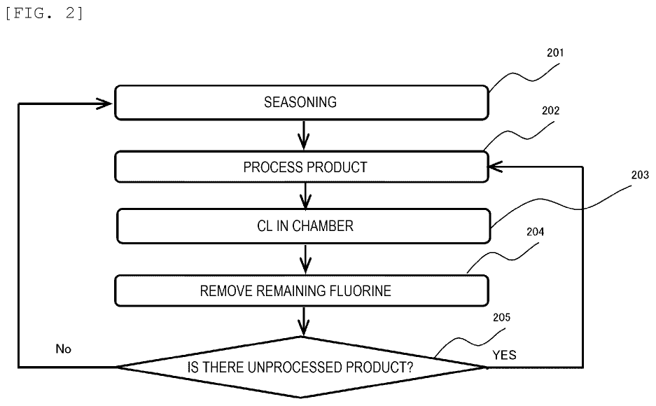

Next, a series of processes including a cleaning processing step of using the plasma etching device shown in FIG. 1 will be described with reference to the drawings. FIG. 2 is a flowchart showing a series of processes executed by the control device CONT according to the program.

In step 201, plasma processing of the wafer is performed under a predetermined condition so that a shape of the first wafer 102 after etching of a lot to be processed does not significantly change as compared with a shape of the second and subsequent wafers 102 after etching. This is referred to as a seasoning step.

Next, in step 202, the wafer 102 is etched (first step). At this time, a byproduct (a particle) adheres to inner wall of the chamber 101.

Thereafter, in step 203, plasma-cleaning is performed in the chamber 101 by introducing a gas (fluorine-containing gas) in which an argon gas and a nitrogen trifluoride gas are mixed into the chamber 101 and generating the plasma 111. A processing pressure at this time is 15 Pa, and the duty ratio of the microwave is 100% (continuous oscillation or continuous discharge). Step 203 is to remove the byproduct adhered to the inner wall of the chamber 101 in step 202 (second step).

Then, step 204 is performed to remove nitrogen and fluorine remaining in the chamber 101 generated in step 203. In step 204, while the pulse-modulated radio frequency power is supplied into the chamber 101, the remaining nitrogen and fluorine are removed (plasma-cleaned) using the plasma generated by introducing the argon gas and an oxygen gas (third step). At this time, the processing pressure is 0.4 Pa, for example, the duty ratio of the microwave is 50%, and the pulse frequency is 1000 Hz.

In addition, if there is an unprocessed wafer in the lot to be processed in step 205, the process returns to step 202 again to perform etching or the like. On the other hand, when there is no unprocessed wafer in the lot, processing of one lot is completed. If there is a next lot, the process returns to step 201, and the seasoning step is performed so as to start etching of the wafer of the next lot.

Next, an effect of removing the nitrogen and fluorine remaining in the chamber 101 in step 204 will be described.

### Embodiment

After cleaning inside the chamber 101 in step 204 is completed under the above conditions, the particle caused by the nitrogen and fluorine adhered to the wafer 102 carried into the chamber 101 were confirmed, but the particle caused by the nitrogen and fluorine cannot be detected. On the other hand, under the condition of step 204, when the duty ratio of the microwave is set to 100% and the same confirmation is performed, the particle caused by the nitrogen and fluorine was observed.

A reason for an occurrence of the particle can be described as follows.

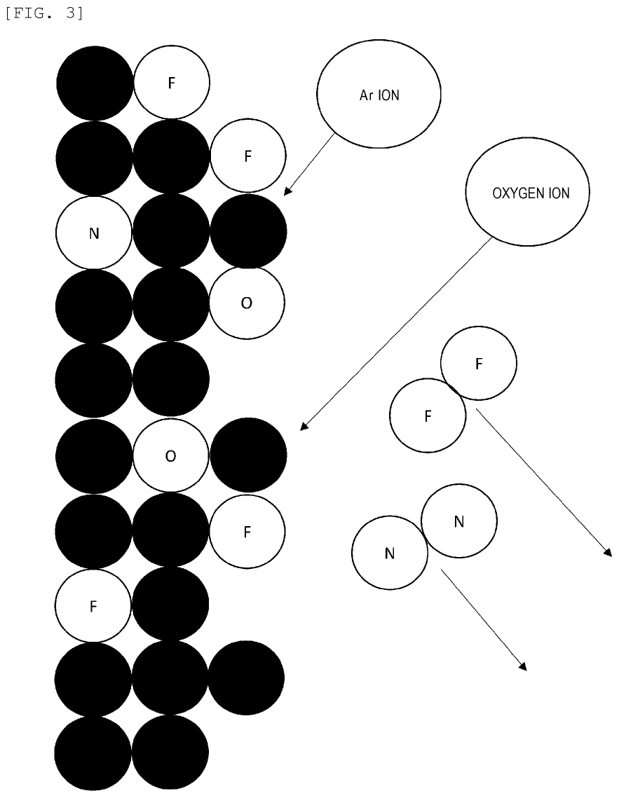

FIG. 3 is a view schematically showing a sidewall of the chamber 101 after the step 203 is completed. Circles shown in black represent constituent elements of the sidewall of the chamber 101.

In step 204, the ions in the generated plasma 111 sputter the sidewall of the chamber 101, or oxygen oxidizes the walls to remove the remaining fluorine and nitrogen elements.

On the other hand, in step 204, the plasma 111 is on by the microwave oscillated from the magnetron 106 and is off by the interruption of the microwave in accordance with the radio frequency power from the radio frequency power supply 110, and the oscillation and the interruption are alternately repeated in a form of a pulse waveform. When the plasma 111 is off, an electron temperature decreases rapidly, and the plasma 111 adsorbs to molecules present in the plasma or diffuses to the sidewall of the chamber 101 and decreases.

Therefore, an electron flux flowing onto the sidewall of the chamber 101 decreases, and a potential of the sidewall of the chamber 101 which is negatively charged increases. On the other hand, since oxygen present in the plasma 111 has a high electron affinity, much of the oxygen exists as negative ions in the plasma 111. Therefore, when the plasma 111 is on, the potential of the sidewall of the chamber 101 is pushed back, and only a small amount of the negative oxygen ions can exist near the sidewall of the chamber 101.

However, when the plasma 111 is off, the potential of the sidewall of the chamber 101 gradually increases. Therefore, more particles having oxygen flow onto the sidewall of the chamber 101. Therefore, the sidewall of the chamber 101 is oxidized, and the nitrogen and fluorine remaining on the sidewall of the chamber 101 can be removed. Therefore, a time during which the plasma is off, which is a time during which the oscillation of the microwave is interrupted, may be longer than or equal to a time during which a negative oxygen ion flux flowing onto the sidewall of the chamber 101 becomes larger than the electron flux flowing onto the sidewall of the chamber 101. In other words, an off time of the pulse may be set equal to or longer than the off time of the plasma during which the negative oxygen ion flux flowing onto the sidewall of the chamber 101 is larger than the electron flux flowing onto the sidewall of the chamber 101.

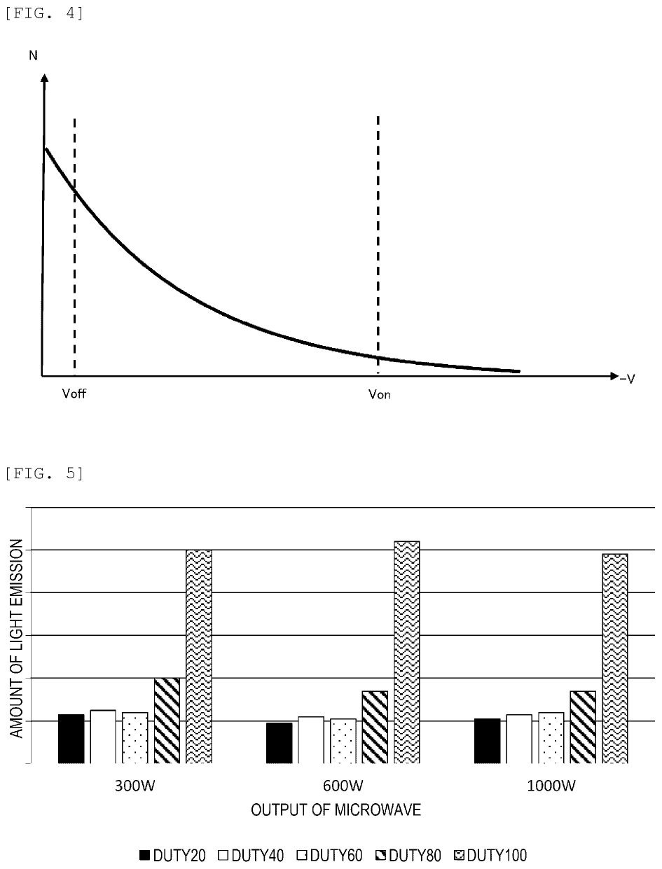

FIG. 4 is a graph showing a relationship between the number of the oxygen ions having negative charges present in the plasma 111 and the potential, which is a support of a theory described above. However, a vertical axis represents the number of particles N and a horizontal axis represents the potential −V of the sidewall of the chamber 101, and the number of particles follows a Boltzmann distribution. Von is the potential of the sidewall of the chamber 101 when the microwave is oscillated, and Voff is the potential of the sidewall after a predetermined time after the oscillation of the microwave is interrupted.

As seen from FIG. 4, when the plasma 111 is off, the number of the ions capable of being present near the sidewall of the chamber 101 increases. From the above, it can be seen that the microwave is more likely to remove the particle when pulse-modulated than when continuously oscillated. The cycle of the pulse of the microwave is preferably 1 millisecond or less.

However, when the off time of the plasma 111 is longer than the time during which the ions in the plasma 111 disappear, the plasma 111 will misfire. Therefore, the maximum off time of the plasma 111 is preferably equal to or less than the time during which the ions in the plasma 111 disappear, and specifically, it is desired to set an oscillation interruption time of the microwave in one cycle in the pulse-modulation to 10 milliseconds or less.

In addition, FIG. 5 is a graph showing the effect of removing the remaining nitrogen and the remaining fluorine in the present embodiment. Here, only a maximum output of the first radio frequency power supply 110 and the duty ratio are changed in step 204 of the above embodiment, and the continuous discharge using only the argon gas is performed in the chamber 101 after step 204, and a time average of the amount of light emission of fluorine in the chamber 101 is shown.

Specifically, a rate of the oscillation time of the microwave to the cycle of the pulse-modulation of the microwave is referred to as a duty ratio (when the duty ratio is 20%, the microwave is oscillated in 20% of the cycle of the pulse-modulation). The larger the amount of light emission of fluorine is, the larger an amount of the remaining fluorine is.

It can be seen from the results of FIG. 5 that even if the maximum output of the first radio frequency power supply 110 changes between 300 W, 600 W, and 1000 W, a tendency of a particle removal effect is almost unchanged. In addition, it can be seen that, while the particle removal effect is the lowest when the duty ratio is 100%, the particle removal effect increases as the duty ratio decreases, and the particle removal effect tends to be high, particularly, when using a certain duty ratio as a threshold value. Therefore, it is desired that an on time of the plasma 111, that is, the oscillation time of the microwave, is set to a value in which the duty ratio is 50% or less while ensuring a margin.

In addition, the invention can be applied to embodiments not limited to the process of FIG. 2. For example, the invention can be applied to any embodiment including at least step 203.

In addition, in the embodiment described above, there is a step of carrying the wafer 102, but embodiments not limited to this can be applied. For example, when the steps 201, 203, and 204 are performed, the wafer 102 may not be carried into the chamber 101.

In addition, although the present embodiment shows a removal example of the nitrogen and fluorine remaining in the chamber 101, but embodiments not limited to this can be applied. For example, the invention can also be applied to the removal of halogen other than the remaining fluorine.

The invention is not limited to the embodiments described above, and includes various modifications. For example, the embodiments described above have been described in detail for easy understanding of the invention, and the invention is not necessarily limited to those including all configurations described above. In addition, a part of the configuration of one embodiment can be replaced with configurations of other embodiments, and the configurations of other embodiment can be added to the configuration of one embodiment. In addition, a part of the configuration of each embodiment may be added, deleted, or replaced with another configuration.

### REFERENCE SIGN LIST

101: chamber
102: wafer
103: sample stage
104: microwave transmission window
105: waveguide
106: magnetron
107: solenoid coil
108: wafer load port
109: gas supply pipe
110: first radio frequency power supply

1. A plasma processing method for plasma processing a sample in a processing chamber, the method comprising:
a first step of plasma processing the sample;
a second step of performing plasma-cleaning inside the processing chamber using a fluorine-containing gas after the first step; and
a third step of performing plasma-cleaning inside the processing chamber using plasma generated by a pulse-modulated radio frequency power and an oxygen gas after the second step.

2. The plasma processing method according to claim 1, wherein
plasma in the second step performs continuous discharge.

3. The plasma processing method according to claim 2, wherein
an off time of the pulse in pulse-modulation is made longer than an off time of the plasma during which a negative ion flux flowing onto an inner wall of the processing chamber is larger than an electron flux flowing onto the inner wall of the processing chamber, or the off time of the pulse is equal to the off time of the plasma.

4. The plasma processing method according to claim 3, wherein
the fluorine-containing gas is a nitrogen trifluoride (NF₃) gas.

5. The plasma processing method according to claim 4, wherein
a duty ratio of the pulse is set to 50% or less, and a cycle of the pulse is set to 1 ms.

6. A plasma processing apparatus, comprising:
a processing chamber configured to perform plasma processing of a sample;
a radio frequency power supply configured to supply a radio frequency power for generating plasma;
a sample stage on which the sample is placed; and
a control device configured to execute a program specifying:
a first step of plasma processing the sample;
a second step of performing plasma-cleaning inside the processing chamber using a fluorine-containing gas after the first step; and
a third step of performing plasma-cleaning inside the processing chamber using plasma generated by a pulse-modulated radio frequency power and an oxygen gas after the second step.
